(19) United States
(12) Patent Application Publication
(10) Pub. No.: US 2022/0147317 A1
(43) Pub. Date: May 12, 2022

(54) DATA PROCESSING DEVICE AND METHOD FOR OPERATING A DATA PROCESSING DEVICE

(71) Applicant: Robert Bosch GmbH, Stuttgart (DE)

(72) Inventors: Jan Hayek, Muenchen (DE); Anton Roman Grad, Sunnyvale, CA (US)

(21) Appl. No.: 17/423,649

(22) PCT Filed: Jan. 8, 2020
(86) PCT No.: PCT/EP2020/050279

§ 371 Date: Jul. 16, 2021

(30) Foreign Application Priority Data
Jan. 29, 2019 (DE) 10 2019 201 094.6

(51) Int. Cl. G06F 7/58; H03K 3/84

(52) U.S. Cl. CPC G06F 7/584; G06F 2207/581; H03K 3/84

(57) ABSTRACT

A method for ascertaining a randomized digital data stream. The method includes ascertaining a first bit stream as a function of an analog input data stream; ascertaining a second randomized bit stream as a function of the first bit stream, the second randomized bit stream being ascertained in a non-periodic temporal sequence; ascertaining a first digital data stream as a function of the second randomized bit stream; ascertaining a second digital data stream including pseudo random numbers; and ascertaining the randomized digital data stream as a function of the first digital data stream and as a function of the second digital data stream.

### FIELD

The present invention relates to a data processing device for ascertaining a randomized data stream and a method for operating a data processing device.

### BACKGROUND INFORMATION

Different sensor systems, such as for example acceleration sensors, rotation rate sensors, pressure sensors, etc., often provide the possibility of expanding the measuring range at the expense of accuracy.

This translates to an increased effort with regard to sensor data postprocessing, since depending on the width of the data values different algorithms must be used for different widths, in order to take into account the digital quantization noise of data values of lower accuracy.

In order to avoid this problem, dithering is often used, i.e., the resulting error is blurred in that a random value in the value range of the “missing width” of the reduced sensor signal is added thereto. Linear feedback shift registers that generate statistically good random numbers depending on the depth are popular as the source of these random values.

### SUMMARY

The object of the present invention may be achieved by a data processing device as well as a method for operating a data processing device, in accordance with example embodiments of the present invention. Advantageous refinements result from the following description of examples.

One first aspect of the present invention relates to a data processing device for ascertaining a randomized digital data stream. In accordance with an example embodiment of the present invention, the data processing device includes: a noise source configured to ascertain a first bit stream; an extractor circuit configured to ascertain a second randomized bit stream as a function of the first bit stream, the extractor circuit ascertaining the second randomized bit stream in a non-periodic temporal sequence; a register circuit configured to ascertain a first digital data stream as a function of the second randomized bit stream; a pseudo random generator circuit configured to ascertain a second digital data stream including pseudo random numbers; and a logic circuit configured to ascertain the randomized digital data stream as a function of the first digital data stream and as a function of the second digital data stream.

The provided data processing device advantageously allows for an implementation requiring little effort in terms of computing power and memory consumption. For example, the data processing device may have a more compact design than a linear feedback shift register having a corresponding length. The number of the necessary bits of the used pseudo random generator circuit may rather be reduced and may be in the range of the generated randomized data stream, for example. The space and power demand for the data processing device is consequently reduced. In particular, the data processing device may be advantageously implemented without software and without microcontrollers, thus allowing for it to be integrated into integrated circuits, in particular ASICs.

Moreover, even minimal changes in the first bit stream result in different random numbers in the randomized digital data stream. The generated randomized data stream is non-deterministic.

Consequently, the provided data processing device represents a real random generator, which makes new applications possible, such as for example cryptographically securing data against manipulation. Additional components are advantageously not needed as the source of the entropy for this random generator, but the components that are already in the system may also be used. This means that the data processing device may have a smaller design and provides better results, from which numerous applications benefit. The generation of a cryptographic key, in particular of a cryptographic session key, may thus be simplified, for example.

One advantageous example is characterized in that the noise source includes a converter circuit configured to ascertain the bit stream as a function of an analog input data stream. The already present or required converter circuit may be advantageously used to generate the first bit stream. The quantization noise of the converter circuit is thus used to ascertain the randomized data stream.

Consequently, components such as a dedicated noise source in the form of a ring oscillator, for example, and a correspondingly complex conditioning circuit, which provides the random numbers, are dispensed with. In this way, the required hardware resources are further reduced.

In one example embodiment of the present invention, the extractor circuit is configured to ascertain the second bit stream including a second mean bit rate as a function of the first bit stream including a higher mean first bit rate as compared to the second bit rate. The pseudo random generator circuit and the logic circuit make it advantageously possible that a generation of the randomized digital data stream is possible despite the non-fixed bit rate of the second bit stream.

In one example embodiment of the present invention, the extractor circuit includes a Von Neumann extractor. The Von Neumann extractor advantageously provides an evenly distributed output.

In one advantageous example embodiment of the present invention, the pseudo random generator circuit includes a linear feedback shift register. A linear feedback shift register may advantageously provide a pseudo random component that—linked to the randomized data stream—always provides a different result in the form of the randomized data stream. The linear feedback shift register may be advantageously dimensioned in such a way that it provides data of a size that corresponds to the size of the randomized digital data stream.

In one advantageous example embodiment of the present invention, the logic circuit is configured to ascertain the digital data stream through an XOR operation of the first digital data stream to the second digital data stream. The XOR operation provides a logic operation, which is to be implemented in a simple manner, in order to ascertain the randomized data stream.

One second aspect of the present invention relates to a method for ascertaining a randomized digital data stream. In accordance with an example embodiment of the present invention, the method includes: ascertaining a first bit stream with the aid of a noise source; ascertaining a second randomized bit stream as a function of the first bit stream, the second randomized bit stream being ascertained in a non-periodic temporal sequence; ascertaining a first digital data stream as a function of the second randomized bit stream; ascertaining a second digital data stream including pseudo random numbers; and ascertaining the randomized digital data stream as a function of the first digital data stream and as a function of the second digital data stream.

### BRIEF DESCRIPTION OF THE DRAWINGS

FIG. 1 schematically shows a data processing device in accordance with example embodiment of the present invention.

FIG. 2 shows one exemplary embodiment for the data processing device in accordance with an example embodiment of the present invention.

### DETAILED DESCRIPTION OF EXAMPLE EMBODIMENTS

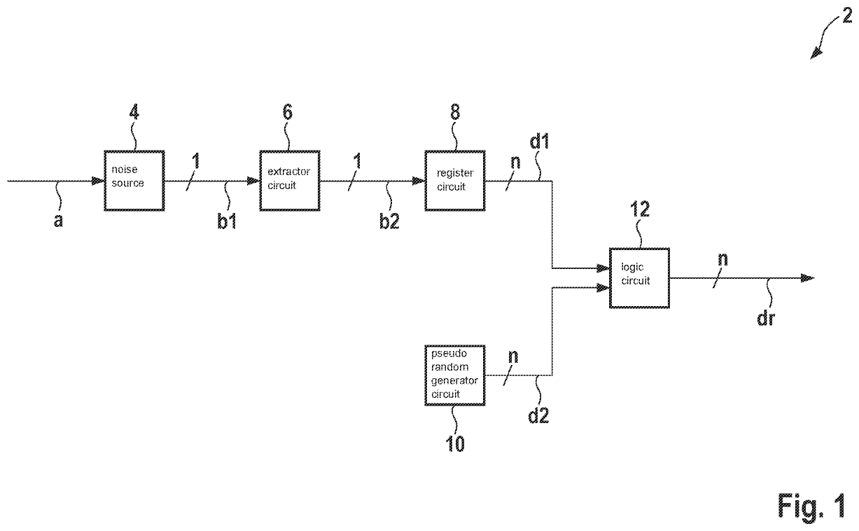

FIG. 1 schematically shows a data processing device 2. A noise source 4 ascertains a first bit stream b1. Noise source 4 includes a converter circuit, for example, which ascertains first bit stream b1 as a function of an analog input data stream a.

An extractor circuit 6 ascertains a second randomized bit stream b2 as a function of first bit stream b1. Extractor circuit 6 is a Von Neumann extractor, for example. Extractor circuit 6 takes consecutive pairs of consecutive bits from first bit stream b1. If the two bits from the particular pair match, no output is generated. If the bits are different, the value of the first bit is output as part of second bit stream b2. Due to these generation rules, second randomized bit stream b2 is not ascertained at a fixed data rate. It may be shown for the Von Neumann extractor that it generates an evenly distributed output, even if the distribution of the input bits is not uniform, as long as each bit has the same probability to be one and there is no correlation between consecutive bits. Consequently, random number bits are collected with the aid of extractor circuit 6 from analog input data stream a, which may also be referred to as sigma-delta data stream.

A register circuit 8 takes second bit stream b2, which is generated in a non-periodic temporal sequence, and generates a first digital data stream d1 including a number of n bits per data word. Register circuit 8 provides first data stream d1 in a periodic temporal sequence, i.e., at a fixed data rate. Register circuit 8 includes a linear shift register and stores the generated random number bits in the incoming sequence, for example. New random numbers are then stored only if extractor circuit 6 indicates a validity of a new data word. The oldest data word is discarded in each case when a new data word is written. Length n of the shift register is identical or greater than a number of random number bits that are required to fill filtered sensor data stream s1. If the shift register of register circuit 8 is longer than the number of the required random number bits, the new random number bits are picked off from any arbitrary spot of the shift register.

A pseudo random generator circuit 10 ascertains a second digital data stream d2 that includes pseudo random numbers and which include a number of n bits per data word. Pseudo random generator circuit 10 provides second data stream d2 in a periodic temporal sequence, i.e., at a fixed data rate. The depth of the shift register of pseudo random generator circuit 10 is arbitrary, but is preferably equal to or greater than m (number of the random number bits required at the same time). The polynomial of the shift register of pseudo random generator circuit 10 is primitive in on example to ensure a maximal period of the linear fed back shift register. If the depth is greater than the number of the required random number bits, any arbitrary bits of the shift register are used as the data source for second data stream s2.

A logic circuit 12 ascertains a randomized data stream dr as a function of first digital data stream d1 and as a function of second digital data stream d2. Particular data words of first and second data streams d1, d2 are linked bitwise with the aid of an XOR operation, in particular. This means that a bitwise XOR operation takes place to ascertain a data word of randomized data stream dr including a number of n bits per data word. Logic circuit 12 provides randomized data stream dr in a period temporal sequence. The XOR operation yields the advantage that the generated random bits of first data stream d1, which originate from extractor circuit 6 and thus do not have a fixed data rate, are masked by second data stream d2 having a fixed data rate.

Consequently, data processing device 2 provides a random number generator that may also be utilized for cryptographic methods in addition to processing sensor data. For example, the random numbers of randomized data stream dr may be utilized in the case of probabilistic signature methods.

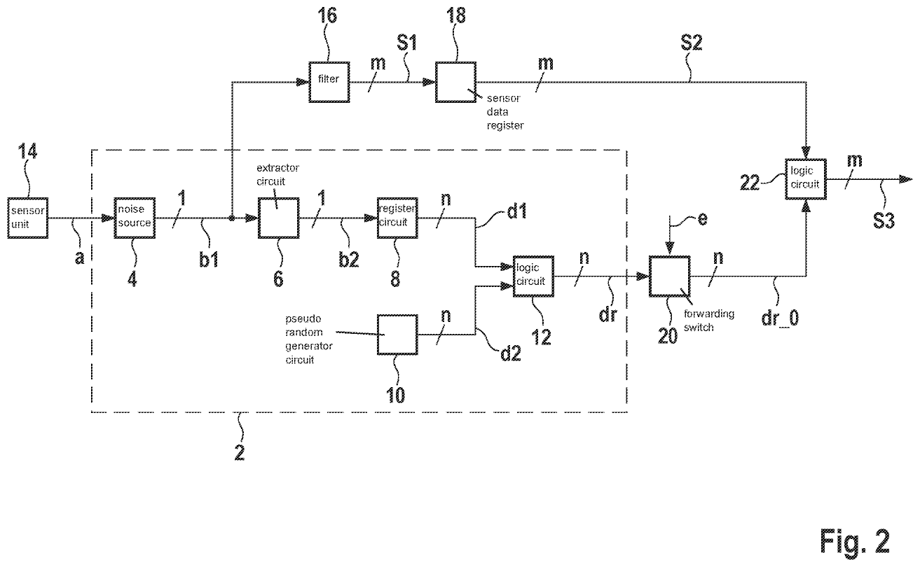

FIG. 2 shows one exemplary embodiment for data processing device 2. A sensor unit 14 ascertains analog input data stream a. After implementing analog input data stream a, corresponding first bit stream b1 is supplied to a filter 16 that converts the received delta-sigma sensor data stream in the form of first bit stream b1 into a first sensor data stream s1, first sensor data stream s1 including a number of m bits per data word. Noise source 4 is consequently also referred to as a delta-sigma converter. The actual width of the filtered sensor data stream may also be smaller, depending on the filter configuration (selection of different measuring ranges/filter configurations). If this is the case, the data word of sensor data stream s1 is extended (attach zeros) to obtain the required width of m. A sensor data register 18 stores the particular instantaneous filtered data word of first sensor data stream s1 and provides same in the form of second sensor data stream s2.

If a switching signal e is supplied to a block 20, block 20 forwards supplied randomized digital data stream dr to a further logic circuit 22 as a further digital data stream dr_0. Logic circuit 22 adds a data word of second sensor data stream s2 and a data word of further digital data stream dr_0 and outputs a third sensor data stream s3. Now, if switching signal e is activated, randomized data words generated by data processing device 2 are added to the data words of second sensor data stream s2, the random numbers of randomized data stream dv_0 bearing signs. The random numbers in the form of data stream dr_0 are necessary when the width of filtered sensor data s2 is too small. If this is not the case, however, (depending on the measuring range/the filter settings) the generation of random numbers is switched off. If switching signal e is deactivated in this case, logic circuit 22 forwards merely second data stream s2 as third data stream s3, since data stream dr_0 merely includes zeros.

1-7. (canceled)

8. A data processing device for ascertaining a randomized digital data stream, the data processing device, comprising:
a noise source configured to generate a first bit stream;
an extractor circuit configured to ascertain a second randomized bit stream as a function of the first bit stream, the extractor circuit configured to ascertain the second randomized bit stream in a non-periodic temporal sequence;
a register circuit configured to ascertain a first digital data stream as a function of the second randomized bit stream;
a pseudo random generator circuit configured to ascertain a second digital data stream including pseudo random numbers, and
a logic circuit configured to ascertain the randomized digital data stream as a function of the first digital data stream and as a function of the second digital data stream.

9. The data processing device as recited in claim 8, wherein the noise source includes a converter circuit configured to ascertain the first bit stream as a function of an analog input data stream.

10. The data processing device as recited in claim 8, wherein the extractor circuit is configured to ascertain the second bit stream including a second mean bit rate as a function of the first bit stream including a higher mean first bit rate as compared to the second bit rate.

11. The data processing device as recited in claim 8, wherein the extractor circuit includes a Von Neumann extractor.

12. The data processing device as recited in claim 8, wherein the pseudo random generator circuit includes a linear feedback shift register.

13. The data processing device as recited in claim 8, wherein the logic circuit is configured to ascertain the randomized digital data stream by a bitwise XOR operation of the first digital data stream to the second digital data stream.

14. A method for ascertaining a randomized digital data stream, the method comprising the following steps:
ascertaining a first bit stream using a noise source;
ascertaining a second randomized bit stream as a function of the first bit stream, the second randomized bit stream being ascertained in a non-periodic temporal sequence;
ascertaining a first digital data stream as a function of the second randomized bit stream;
ascertaining a second digital data stream including pseudo random numbers; and
ascertaining the randomized digital data stream as a function of the first digital data stream and as a function of the second digital data stream.
